(19) United States
(12) Patent Application Publication
(10) Pub. No.: US 2026/0214904 A1
(43) Pub. Date: Jul. 23, 2026

(54) SEMICONDUCTOR STORAGE DEVICE

(71) Applicant: Kioxia Corporation, Tokyo (JP)

(72) Inventors: Shinji NAKADA, Yokkaichi Mie (JP); Shota KASHIYAMA, Mie Mie (JP)

(21) Appl. No.: 19/315,371

(22) Filed: Aug. 29, 2025

(30) Foreign Application Priority Data
Jan. 17, 2025 (JP) 2025-006730

(51) Int. Cl. H10B 43/35; H10B 43/10; H10B 43/27; H10B 43/40

(52) U.S. Cl. CPC H10B 43/35; H10B 43/10; H10B 43/27; H10B 43/40

(57) ABSTRACT

A semiconductor storage device includes a stacked body, a plurality of main partitioning structures, a plurality of main pillar structures, and a sub-partitioning structure. In the stacked body, a plurality of conductive layers are stacked in a first direction. The main partitioning structures extend in the stacked body in the first direction and a second direction to partition the plurality of conductive layers in a third direction. The main pillar structures each extend in the stacked body in the first direction and each include a first laminate of layers. The sub-partitioning structure extends in the stacked body in the first and second directions to partition one or more conductive layers in the third direction between adjacent main partitioning structures. The sub-partitioning structure includes second and third laminates of layers. Materials of the second and third laminates are same as materials of the first laminate, respectively.

### CROSS-REFERENCE TO RELATED APPLICATIONS

This application is based upon and claims the benefit of priority from Japanese Patent Application No. 2025-006730, filed Jan. 17, 2025, the entire contents of which are incorporated herein by reference.

### FIELD

Embodiments described herein relate generally to a semiconductor storage device.

### BACKGROUND

For NAND non-volatile semiconductor storage devices that have a three-dimensional structure, improved read performance is in demand.

### BRIEF DESCRIPTION OF THE DRAWINGS

FIG. 1 is a diagram schematically illustrating an overall configuration of a semiconductor storage device according to an embodiment.

FIG. 2 schematically illustrates a planar pattern view of a memory region of the semiconductor storage device according to the embodiment.

FIG. 3 schematically illustrates another planar pattern view of the memory region of the semiconductor storage device according to the embodiment.

FIG. 4 schematically illustrates a cross-sectional view of the semiconductor storage device according to the embodiment.

FIG. 5A schematically illustrates a cross-sectional view of the memory region of the semiconductor storage device according to the embodiment.

FIG. 5B schematically illustrates another cross-sectional view of the memory region of the semiconductor storage device according to the embodiment.

FIG. 5C schematically illustrates another cross-sectional view of the memory region of the semiconductor storage device according to the embodiment.

FIG. 6A schematically illustrates a cross-sectional view of a pillar structure and the like of the semiconductor storage device according to the embodiment.

FIG. 6B schematically illustrates another cross-sectional view of the pillar structure and the like of the semiconductor storage device according to the embodiment.

FIG. 6C schematically illustrates another cross-sectional view of the pillar structure and the like of the semiconductor storage device according to the embodiment.

FIG. 7A schematically illustrates a cross-sectional view of a first sub-partitioning structure and the like of the semiconductor storage device according to the embodiment.

FIG. 7B schematically illustrates another cross-sectional view of the first sub-partitioning structure and the like of the semiconductor storage device according to the embodiment.

FIG. 7C schematically illustrates another cross-sectional view of the first sub-partitioning structure and the like of the semiconductor storage device according to the embodiment.

FIG. 8A is a cross-sectional diagram schematically illustrating a part of a manufacturing method of the semiconductor storage device according to the embodiment.

FIG. 8B is a cross-sectional diagram schematically illustrating a part of the manufacturing method of the semiconductor storage device according to the embodiment.

FIG. 8C is a cross-sectional diagram schematically illustrating a part of the manufacturing method of the semiconductor storage device according to the embodiment.

FIG. 8D is a cross-sectional diagram schematically illustrating a part of the manufacturing method of the semiconductor storage device according to the embodiment.

FIG. 8E is a cross-sectional diagram schematically illustrating a part of the manufacturing method of the semiconductor storage device according to the embodiment.

FIG. 8F is a cross-sectional diagram schematically illustrating a part of the manufacturing method of the semiconductor storage device according to the embodiment.

FIG. 8G is a cross-sectional diagram schematically illustrating a part of the manufacturing method of the semiconductor storage device according to the embodiment.

FIG. 8H is a cross-sectional diagram schematically illustrating a part of the manufacturing method of the semiconductor storage device according to the embodiment.

FIG. 8I is a cross-sectional diagram schematically illustrating a part of the manufacturing method of the semiconductor storage device according to the embodiment.

FIG. 8J is a cross-sectional diagram schematically illustrating a part of the manufacturing method of the semiconductor storage device according to the embodiment.

FIG. 8K is a cross-sectional diagram schematically illustrating a part of the manufacturing method of the semiconductor storage device according to the embodiment.

FIG. 8L is a cross-sectional diagram schematically illustrating a part of the manufacturing method of the semiconductor storage device according to the embodiment.

FIG. 9 is a cross-sectional diagram schematically illustrating a configuration of a semiconductor storage device according to a modification of the embodiment.

### DETAILED DESCRIPTION

In general, according to an embodiment, a semiconductor storage device includes a stacked body, a plurality of main partitioning structures, a plurality of main pillar structures, a first sub-partitioning structure, and a source region. In the stacked body, a plurality of conductive layers are stacked and spaced apart from one another in a first direction. The stacked body includes first, second, and third stacked-body portions. The first stacked-body portion includes one or more first conductive layers included in the plurality of conductive layers and each functioning as a first select gate line for a NAND string. The second stacked-body portion includes one or more second conductive layers included in the plurality of conductive layers and each functioning as a second select gate line for the NAND string. The third stacked-body portion includes a plurality of third conductive layers provided between the first stacked-body portion and the second stacked-body portion and included in the plurality of conductive layers, the plurality of third conductive layers each functioning as a word line for the NAND string. The plurality of main partitioning structures each extend in the first direction and a second direction intersecting the first direction in the stacked body to partition the plurality of conductive layers in a third direction intersecting the first and second directions. The plurality of main partitioning structures include a first main partitioning structure and a second main partitioning structure that are adjacent to each other in the third direction. The plurality of main pillar structures are provided between the first and second main partitioning structures in the third direction. Each of the plurality of main pillar structures extends in the first direction in the stacked body and functions as the NAND string. Each of the plurality of main pillar structures includes a first laminate of layers formed inward from an outer peripheral surface of the main pillar structure. The first laminate of layers includes a first semiconductor layer and extends in the first direction along the outer peripheral surface. The first sub-partitioning structure is provided between the first and second main partitioning structures in the third direction, provided to include a first side surface and a second side surface that are opposite to each other in the third direction, and extending in the first stacked-body portion in the first and second directions without extending in the second and third stacked-body portions to partition the one or more first conductive layers in the third direction between the first and second main partitioning structures. The first sub-partitioning structure includes a first stacked-film portion and a second stacked-film portion. The first stacked-film portion is of a second laminate of layers formed inward from the first side surface. The second laminate of layers includes a second semiconductor layer and extends in the first and second directions along the first side surface. The second stacked-film portion is of a third laminate of layers formed inward from the second side surface. The third laminate of layers includes a third semiconductor layer and extends in the first and second directions along the second side surface. The second stacked-film portion is opposite to the first stacked-film portion in the third direction. The source region is provided on a side of a first end surface of the stacked body in the first direction. The source region is electrically connected to a first end portion in the first direction of the first semiconductor layer included in each of the plurality of main pillar structures. Materials of the second laminate of layers formed inward from the first side surface in the first stacked-film portion are same as materials of the first laminate of layers formed inward from the outer peripheral surface in each of the plurality of main pillar structures, respectively. Materials of the third laminate of layers formed inward from the second side surface in the second stacked-film portion are same as the materials of the first laminate of layers formed inward from the outer peripheral surface in each of the plurality of main pillar structures, respectively.

An embodiment will now be described with reference to the drawings.

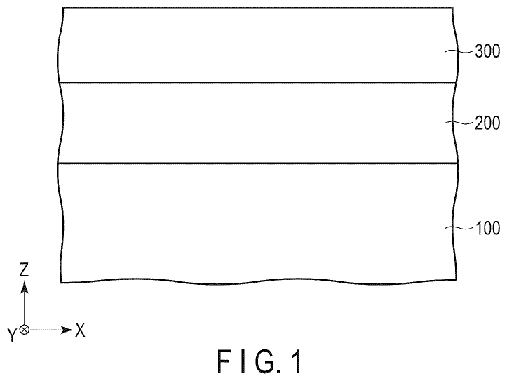

FIG. 1 is a diagram schematically illustrating an overall configuration of a semiconductor storage device according to an embodiment.

As illustrated in FIG. 1, the semiconductor storage device according to the embodiment includes a semiconductor substrate 100, a control-circuit region 200, and a memory region 300. Specifically, the control-circuit region 200 is provided between the semiconductor substrate 100 and the memory region 300.

The memory region 300 is provided with a NAND non-volatile semiconductor memory that has a three-dimensional structure, and the control-circuit region 200 is provided with a control circuit that controls the operation of the memory region 300.

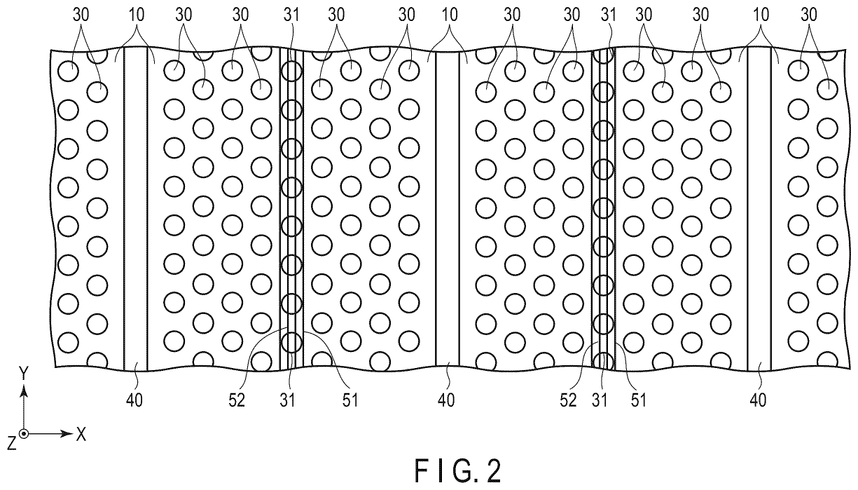

FIG. 2 schematically illustrates a planar pattern view of the memory region 300.

The memory region 300 includes a stacked body 10, a plurality of pillar structures (main pillar structures) 30, a plurality of dummy pillar structures 31, a plurality of partitioning structures (main partitioning structures) 40, a plurality of sub-partitioning structures (first sub-partitioning structures) 51, and a plurality of sub-partitioning structures (second sub-partitioning structures) 52.

The stacked body 10 has a structure in which a plurality of conductive layers to be described below in detail are stacked in a Z-direction. A plurality of pillar structures 30 are arranged in X- and Y-directions, and each pillar structure 30 extends in the stacked body 10 in the Z-direction. A plurality of partitioning structures 40 are arranged in the X-direction, and each partitioning structure 40 extends in the stacked body 10 in the Y- and Z-directions. A plurality of partitioning structures 40 partition a plurality of conductive layers included in the stacked body 10 into a plurality of groups in the X-direction. When viewed from another aspect, a plurality of partitioning structures 40 partition a plurality of pillar structures 30 into a plurality of groups in the X-direction.

The X-direction, the Y-direction, and the Z-direction are mutually intersecting directions. In a specific implementation, the X-direction, the Y-direction, and the Z-direction are perpendicular to one another.

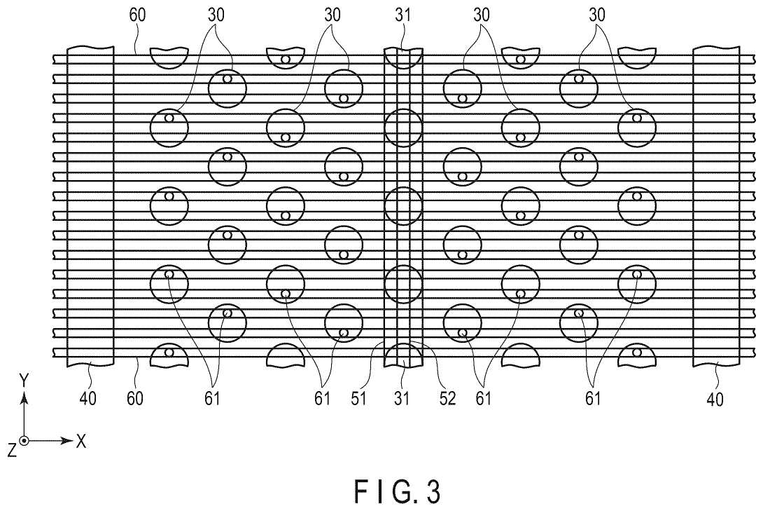

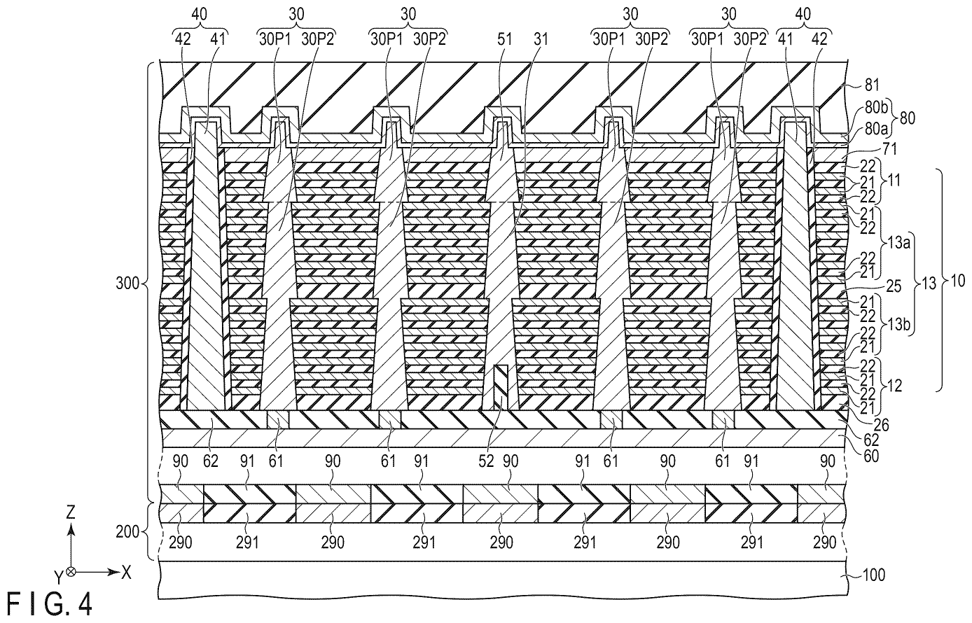

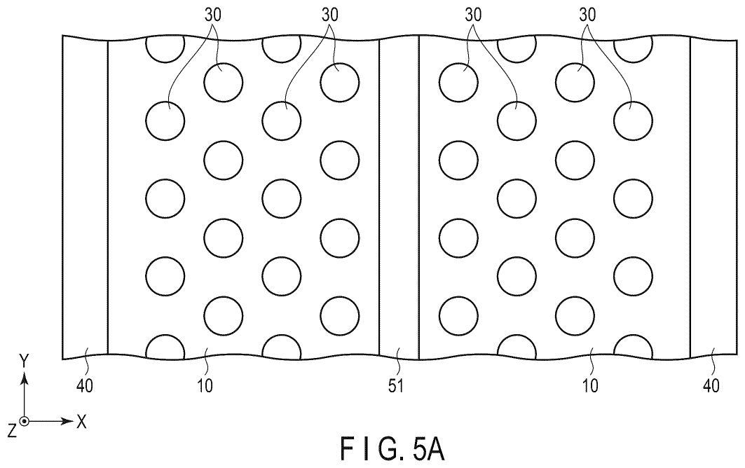

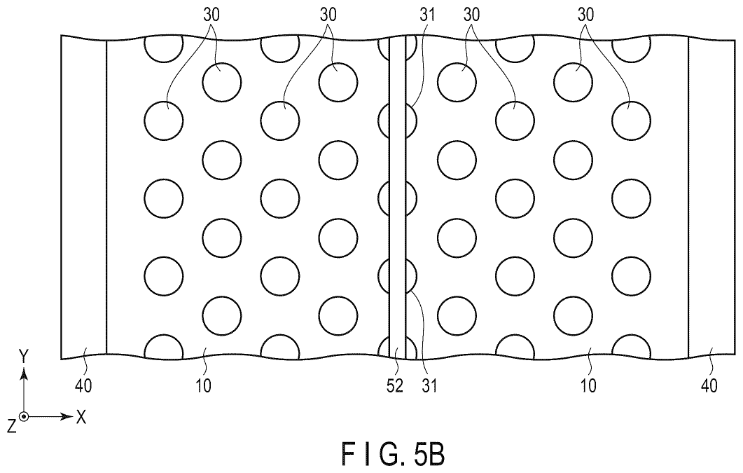

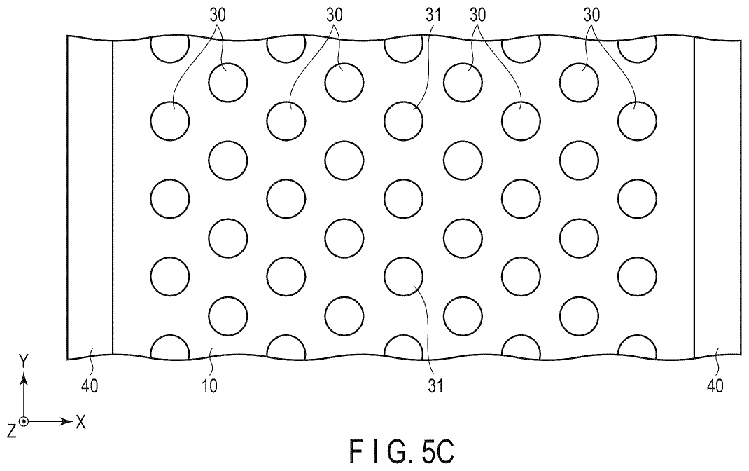

Next, a more specific configuration of the semiconductor storage device according to the embodiment will be described with reference to FIG. 3, FIG. 4, FIG. 5A, FIG. 5B, and FIG. 5C. It is noted that these drawings mainly schematically illustrate the partitioning structures 40 that are adjacent to each other in the X-direction (adjacent partitioning structures) and a configuration between the adjacent partitioning structures 40.

FIG. 3 schematically illustrates a planar pattern view of the memory region 300. FIG. 4 schematically illustrates a cross-sectional view of the semiconductor substrate 100, the control-circuit region 200, and the memory region 300 and mainly schematically illustrates a configuration of the memory region 300. FIG. 5A, FIG. 5B, and FIG. 5C each schematically illustrate a cross-sectional view of the memory region 300 corresponding to first, second, and third stacked-body portions to be described below in detail.

As illustrated in FIG. 4, the control-circuit region 200 is provided on the semiconductor substrate 100, and the memory region 300 is provided on the control-circuit region 200.

The control-circuit region 200 and the memory region 300 are separately formed, and the separately formed control-circuit region 200 and memory region 300 are bonded together. Specifically, the memory region 300 is provided with a plurality of bonding electrodes 90 isolated by an insulating layer 91, and the control-circuit region 200 is provided with a plurality of bonding electrodes 290 isolated by an insulating layer 291, so that the memory region 300 and the control-circuit region 200 are bonded together by the bonding electrodes 90 and the bonding electrodes 290.

The configuration of the memory region 300 will now be described in detail.

The stacked body 10 has a structure in which a plurality of conductive layers 21 are stacked and spaced apart from one another in the Z-direction. Specifically, the stacked body 10 has a structure in which a plurality of conductive layers 21 and a plurality of insulating layers 22 are alternately stacked in the Z-direction.

The stacked body 10 includes a stacked-body portion (first stacked-body portion) 11, a stacked-body portion (second stacked-body portion) 12, and a stacked-body portion (third stacked-body portion) 13 provided between the stacked-body portion 11 and the stacked-body portion 12.

The stacked-body portion 11 includes one or more conductive layers (first conductive layers) 21 that each function as a source-side select gate line (first select gate line) for a NAND string. The stacked-body portion 12 includes one or more conductive layers (second conductive layers) 21 that each function as a drain-side select gate line (second select gate line) for a NAND string. In the embodiment, the stacked-body portion 11 and the stacked-body portion 12 each include a plurality of conductive layers 21. The stacked-body portion 13 includes a plurality of conductive layers (third conductive layers) 21 that each function as a word line for a NAND string.

The stacked-body portion 13 includes a sub-stacked portion 13a and a sub-stacked portion 13b, and an insulating layer 25 is provided between the sub-stacked portion 13a and the sub-stacked portion 13b. A semiconductor layer 71 is provided on the side of a first end surface of the stacked body 10 in the Z-direction (an end surface on the side on which a source region 80 is provided), and an insulating layer 26 is provided on the side of a second end surface of the stacked body 10 in the Z-direction (an end surface on the side on which a bit line 60 is provided).

As already described, a plurality of pillar structures 30 are arranged in the X- and Y-directions, and each pillar structure 30 extends in the stacked body 10 in the Z-direction. That is, each pillar structure 30 penetrates the stacked-body portion 11, the stacked-body portion 12, and the stacked-body portion 13 of the stacked body 10.

Each pillar structure 30 functions as a NAND string. Specifically, a source-side select gate of the NAND string is formed from one or more conductive layers 21 included in the stacked-body portion 11 and portions of the pillar structures 30 surrounded by such one or more conductive layers 21. Furthermore, a drain-side select gate of the NAND string is formed from one or more conductive layers 21 included in the stacked-body portion 12 and portions of the pillar structures 30 surrounded by such one or more conductive layers 21. Furthermore, a memory cell of the NAND string is formed from a plurality of conductive layers 21 included in the stacked-body portion 13 and portions of the pillar structures 30 surrounded by the conductive layers 21.

A pillar structure portion (first pillar structure portion) 30P1, which includes a portion provided in the stacked-body portion 11, penetrates the semiconductor layer 71 in addition to the stacked-body portion 11 and reaches the source region 80 to be described below in detail.

Furthermore, a pillar structure portion (second pillar structure portion) 30P2, which includes a portion provided in the stacked-body portions 12 and 13, penetrates the insulating layer 26 in addition to the stacked-body portions 12 and 13 and is connected to the bit line 60 via a contact electrode 61 to be described in detail. It is noted that FIG. 4 illustrates basically a cross-sectional view taken along lines passing through the centers of a plurality of pillar structures 30 arranged in the X-direction. Accordingly, the contact electrode 61, which would otherwise be invisible in the cross-sectional view of FIG. 4, is also illustrated in FIG. 4 for facilitating understanding of the description.

A side surface of the pillar structure 30 has a step at a boundary between a side surface of the pillar structure portion 30P1 and a side surface of the pillar structure portion 30P2. In other words, the side surface of the pillar structure 30 has a step at a position corresponding to a position in a plane including a boundary between the stacked-body portion 11 and the stacked-body portion 13.

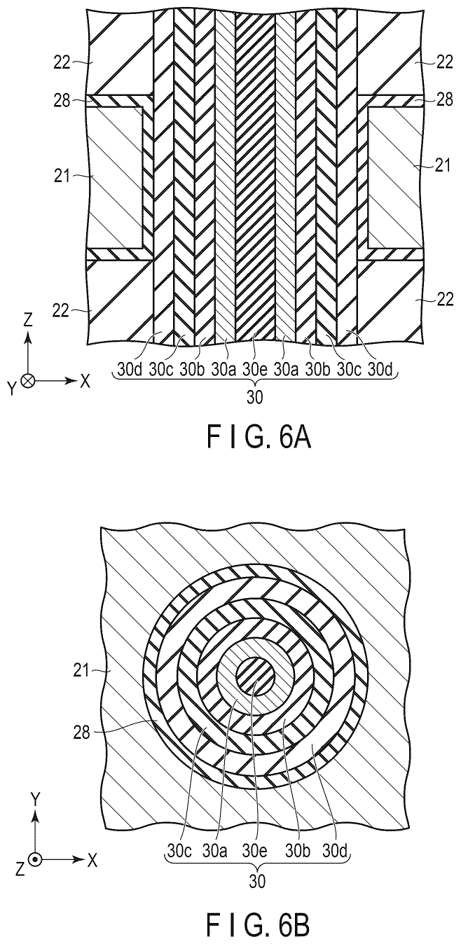

Each of FIG. 6A, FIG. 6B, and FIG. 6C schematically illustrates a cross-sectional view of the pillar structure 30 and the like. FIG. 6A illustrates a cross-sectional view that is parallel to the Z-direction and schematically illustrates a configuration of a portion that includes the pillar structure 30, a conductive layer 21, and an insulating layer 22. FIG. 6B illustrates a cross-sectional view that is perpendicular to the Z-direction and schematically illustrates a configuration of a portion that includes the pillar structure 30, the conductive layer 21, and an insulating layer 28. FIG. 6C illustrates a cross-sectional view that is parallel to the Z-direction and schematically illustrates a configuration of a portion that includes the pillar structure 30, the semiconductor layer 71, and the source region 80.

The pillar structure 30 includes a structure which includes a semiconductor layer 30a and in which a plurality of layers (first laminate of layers) extending in the Z-direction along the outer peripheral surface (the semiconductor layer 30a, a tunnel insulating layer 30b, a charge accumulation layer 30c, and a block insulating layer 30d) are built up inward from the side of the outer peripheral surface. The pillar structure 30 also includes a core insulating layer 30e that extends in the Z-direction inward from such a plurality of layers 30a, 30b, 30c, and 30d. Each of a plurality of layers (the semiconductor layer 30a, the tunnel insulating layer 30b, the charge accumulation layer 30c, and the block insulating layer 30d) has a tubular shape, and the core insulating layer 30e has a columnar shape.

More specifically, the semiconductor layer 30a surrounds the side surface of the core insulating layer 30e, the tunnel insulating layer 30b surrounds the side surface of the semiconductor layer 30a, the charge accumulation layer 30c surrounds the side surface of the tunnel insulating layer 30b, and the block insulating layer 30d surrounds the side surface of the charge accumulation layer 30c. For example, the semiconductor layer 30a is made of silicon, the tunnel insulating layer 30b is made of silicon oxide, the charge accumulation layer 30c is made of silicon nitride, the block insulating layer 30d is made of silicon oxide, and the core insulating layer 30e is made of silicon oxide. That is, any other layers 30b, 30c, 30d, and 30e than the semiconductor layer 30a are insulating layers.

As illustrated in FIG. 6C, the tunnel insulating layer 30b, the charge accumulation layer 30c, and the block insulating layer 30d are not provided in a first end portion of the pillar structure 30 in the Z-direction, and the semiconductor layer 30a is connected to a semiconductor layer 80a included in the source region 80 described below.

Furthermore, as illustrated in FIG. 6A and FIG. 6B, an aluminum oxide layer is provided on a surface of the conductive layer 21 as the insulating layer 28.

As already described, each of a plurality of partitioning structures 40 extends in the stacked body 10 in the Y- and Z-directions. That is, each of a plurality of partitioning structures 40 penetrates the stacked-body portion 11, the stacked-body portion 12, and the stacked-body portion 13 of the stacked body 10, and a plurality of conductive layers 21 included in the stacked body 10 are partitioned into a plurality of groups in the X-direction by the partitioning structures 40.

Each partitioning structure 40 includes a conductive layer 41 that extends in the Y- and Z-directions and an insulating layer 42 that extends in the Y- and Z-directions along opposite side surfaces of the conductive layer 41, and the conductive layer 41 and the stacked body 10 are insulated by the insulating layer 42.

The sub-partitioning structure 51 is provided between adjacent partitioning structures 40 and extends in the stacked-body portion 11 in the Y- and Z-directions. That is, the sub-partitioning structure 51 extends in the stacked-body portion 11 in the Y- and Z-directions without extending in the stacked-body portions 12 and 13 to partition off all of one or more conductive layers 21 included in the stacked-body portion 11 between adjacent partitioning structures 40 in the X-direction. That is, the sub-partitioning structure 51 separates one or more conductive layers 21 that function as a source-side select gate line into two groups between adjacent partitioning structures 40.

In the embodiment, the distance between one of adjacent partitioning structures 40 and the sub-partitioning structure 51 in the X-direction and the distance between the other of adjacent partitioning structures 40 and the sub-partitioning structure 51 in the X-direction are substantially the same. In other words, the number of rows of the pillar structures 30 arranged in the form of row along the Y-direction between one of adjacent partitioning structures 40 and the sub-partitioning structure 51 (the number of rows of one part) and the number of rows of the pillar structure 30 arranged in the form of row along the Y-direction between the other of adjacent partitioning structures 40 and the sub-partitioning structure 51 (the number of rows of the other part) are the same. However, when the number of rows of the pillar structures 30 provided between one of the partitioning structures 40 and the other of the partitioning structures 40 is an odd number, it is preferable to arrange the sub-partitioning structures 51 such that the difference between the number of rows of one part and the number of rows of the other part is one.

Furthermore, no partitioning structure that has a structure similar to the sub-partitioning structure 51 described above is provided between adjacent partitioning structures 40 except the sub-partitioning structure 51 described above. That is, except the sub-partitioning structure 51 described above, no partitioning structure is provided, which extends in the stacked-body portion 11 in the Y- and Z-direction without extending in the stacked-body portions 12 and 13 to partition off all of one or more conductive layers 21 included in the stacked-body portion 11 between adjacent partitioning structures 40 in the X-direction.

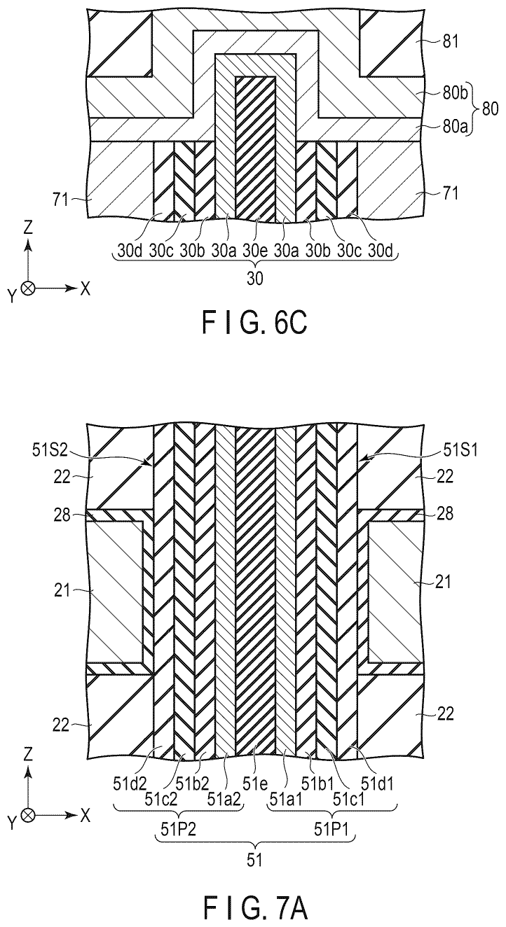

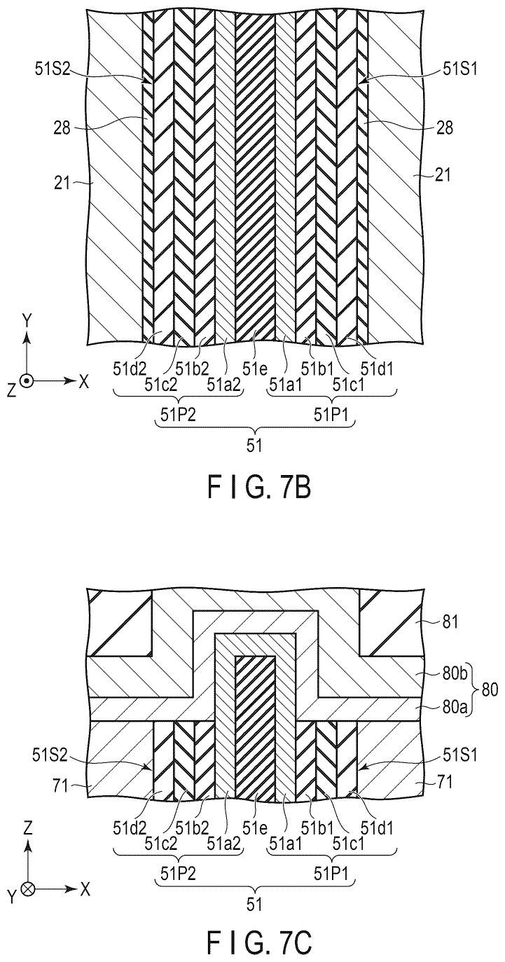

Each of FIG. 7A, FIG. 7B, and FIG. 7C schematically illustrates a cross-sectional view of the sub-partitioning structure 51 and the like. FIG. 7A illustrates a cross-sectional view that is parallel to the Z-direction and schematically illustrates a configuration of a portion that includes the sub-partitioning structure 51, the conductive layer 21, and the insulating layer 22. FIG. 7B illustrates a cross-sectional view that is perpendicular to the Z-direction and schematically illustrates a configuration of a portion that includes the sub-partitioning structure 51, the conductive layer 21, and the insulating layer 28. FIG. 7C illustrates a cross-sectional view that is parallel to the Z-direction and schematically illustrates a configuration of a portion that includes the sub-partitioning structure 51, the semiconductor layer 71, and the source region 80.

The sub-partitioning structure 51 has a structure in which a plurality of layers extend in the Y- and Z-directions along two side surfaces that are opposite to each other in the X-direction. Specifically, the sub-partitioning structure 51 includes a stacked-film portion (first stacked-film portion) 51P1 in which a plurality of layers (second laminate of layer including layers 51a1, 51b1, 51c1, and 51d1), which include a semiconductor layer 51a1 and extend in the Y-and Z-directions along a first side surface 51S1, are built up inward from the side of the first side surface 51S1, and a stacked-film portion (second stacked-film portion) 51P2 in which a plurality of layers (third laminate of layers including layers 51a2, 51b2, 51c2, and 51d2), which include a semiconductor layer 51a2 and extend in the Y- and Z-directions along a second side surface 51S2, are built up inward from the side of the second side surface 51S2. The sub-partitioning structure 51 also includes a layer 51e that extends in the Y- and Z-directions between the stacked-film portion 51P1 and the stacked-film portion 51P2. The layers 51a1, 51b1, 51c1, 51d1, 51a2, 51b2, 51c2, 51d2, and 51e each have a plate-like shape.

As illustrated in FIG. 7C, the layers 51b1, 51c1, 51d1, 51b2, 51c2, and 51d2 are not provided in the first end portion of the sub-partitioning structure 51 in the Z-direction, and the layers 51a1 and 51a2 are connected to the semiconductor layer 80a included in the source region 80 described below.

Furthermore, as described below, the pillar structure 30 is formed by filling a hole for the pillar structure 30 with a plurality of layers for the pillar structure 30. The sub-partitioning structure 51 is formed by filling a trench for the sub-partitioning structure 51 with a plurality of layers. The process of filling the hole for the pillar structure 30 with a plurality of layers and the process of filling the trench for the sub-partitioning structure 51 with a plurality of layers are carried out in the common processes.

Accordingly, the sub-partitioning structure 51 is made of a constituent material that is the same as the constituent material of the pillar structure 30. Specifically, the material of each layer of a plurality of layers (layers 51a1, 51b1, 51c1, and 51d1) built up inward from the side of the first side surface 51S1 in the stacked-film portion 51P1 and the material of each layer of a plurality of layers (layers 51a2, 51b2, 51c2, and 51d2) built up inward from the side of the second side surface 51S2 in the stacked-film portion 51P2 are the same as the material of each corresponding layer of a plurality of layers (layers 30a, 30b, 30c, and 30d) built up inward from the side of the outer peripheral surface of the pillar structure 30. The layer 51e of the sub-partitioning structure 51 is also made of a material that is the same as the layer 30e of the pillar structure 30.

Each of a plurality of dummy pillar structures 31 extends in the Z-direction at least up to the sub-partitioning structure 51 in the stacked-body portion 13 and is unfunctional as a NAND string. As viewed in the Z-direction, a plurality of dummy pillar structures 31 are arranged in the Y-direction such that they overlap the sub-partitioning structure 51. As viewed in the Z-direction, a plurality of dummy pillar structures 31 are also arranged such that the position of the center in the X-direction of the pattern of each of the dummy pillar structures 31 substantially corresponds to the position of the center in the X-direction of the pattern of the sub-partitioning structure 51. Note that the maximum width in the X-direction of the pattern of each dummy pillar structure 31 (the diameter of the dummy pillar structure 31) may be the same as, larger than, or smaller than the width in the X-direction of the pattern of the sub-partitioning structure 51.

Furthermore, the sub-partitioning structure 51 and the pillar structure portion 30P1 of the pillar structure 30 each include a portion provided in the stacked-body portion 11, and a trench for forming the sub-partitioning structure 51 and a hole for forming the pillar structure portion 30P1 are formed in the common processes as described below. A hole for forming the dummy pillar structure 31 and a hole for forming the pillar structure portion 30P2 of the pillar structure 30 are also formed in the common processes. Accordingly, with a surface that includes the first end face of the stacked body 10 (the end face on the side on which the source region 80 is provided) being as a reference surface, the distance from the reference surface (the height from the reference surface) to the boundary between the pillar structure portion 30P1 and the pillar structure portion 30P2 corresponds to (substantially the same as) the distance from the reference surface (the height from the reference surface) to the boundary between the sub-partitioning structure 51 and the dummy pillar structure 31.

The basic configuration of each dummy pillar structure 31 is the same as the configuration of the pillar structure 30 illustrated in FIG. 6A and FIG. 6B. That is, the dummy pillar structure 31 includes a structure in which a plurality of layers (fourth laminate of layers), which include a semiconductor layer and extend in the Z-direction along the outer peripheral surface, are built up inward from the side of the outer peripheral surface, and the material of each layer of a plurality of layers built up inward from the side of the outer peripheral surface of the dummy pillar structure 31 is the same as the material of each corresponding layer of a plurality of layers built up inward from the side of the outer peripheral surface of the pillar structure 30.

Furthermore, at the same distance from the reference surface that includes the first end face of the stacked body 10, the size and shape of a cross-sectional plane perpendicular to the Z-direction of the dummy pillar structure 31 are substantially the same as the size and shape of a cross-sectional plane perpendicular to the Z-direction of the pillar structure 30.

The sub-partitioning structure (second sub-partitioning structure) 52 is made of an insulating material, is provided between adjacent partitioning structures 40, and extends in the stacked-body portion 12 in the Y- and Z-directions. That is, the sub-partitioning structure 52 extends in the stacked-body portion 12 in the Y- and Z-directions without extending in the stacked-body portions 11 and 13 to partition off all of one or more conductive layers 21 included in the stacked-body portion 12 between adjacent partitioning structures 40 in the X-direction. Accordingly, the sub-partitioning structure 52 separates one or more conductive layers 21 that each function as a drain-side select gate line into two groups between adjacent partitioning structures 40.

Furthermore, as viewed in the Z-direction, the position in the X-direction of sub-partitioning structure 52 corresponds to the position in the X-direction of the sub-partitioning structure 51. That is, the sub-partitioning structure 52 extends in the Y-direction such that it overlaps the sub-partitioning structure 51.

The source region 80 is a conductive region and includes the semiconductor layer 80a and a metal layer 80b. The source region 80 is covered with an insulating region 81.

The source region 80 is electrically connected to the first end portion of the semiconductor layer 30a included in each of a plurality of pillar structures 30. Specifically, the first end portion of each semiconductor layer 30a reaches the source region 80, and the source region 80 physically connected to the first end portion of the semiconductor layer 30a included in each of a plurality of pillar structures 30. Accordingly, the semiconductor layer 30a included in each of a plurality of pillar structures 30 provided between adjacent partitioning structures 40 can be supplied with a common voltage from the source side of a NAND string.

The first end portion of the partitioning structure 40 and the first end portion of the sub-partitioning structure 51 also reach the source region 80 and are physically connected to the source region 80.

A plurality of bit lines 60 are provided on the side of the stacked-body portion 12 of the stacked body 10. Such a plurality of bit lines 60 are arranged in the Y-direction and each of the bit lines 60 extends in the X-direction.

Each bit line 60 is electrically connected to the second end portion in the Z-direction of the semiconductor layer 30a included in each of a plurality of predetermined pillar structures 30 among a plurality of pillar structures 30 via the contact electrode 61. Specifically, as illustrated in FIG. 3, each bit line 60 is provided such that it overlaps a plurality of pillar structures 30 arranged in the form of row along the X-direction. In the embodiment, two bit lines 60 are provided such that they overlap each row of a plurality of pillar structures 30 arranged along the X-direction. Furthermore, as already described, one or more conductive layers 21 included in the stacked-body portion 11 are separated into two groups between adjacent partitioning structures 40 by the sub-partitioning structure 51 provided between adjacent partitioning structures 40. Such a plurality of pillar structures 30 arranged in each row of the X-direction includes two pillar structures 30 along the X-direction in each group isolated by the sub-partitioning structure 51, and two bit lines 60 are connected to the two pillar structures 30, one for each, via contacts 61.

As described above, in the embodiment, all of one or more conductive layers 21 included in the stacked-body portion 11 are partitioned off in the X-direction by the sub-partitioning structure 51 provided between adjacent partitioning structures 40. That is, one or more conductive layers 21 that function as source-side select gate line for a NAND string are all electrically separated by the sub-partitioning structure 51 in the X-direction. Accordingly, it is possible to separately control a source-side select gate line provided between one of adjacent partitioning structures 40 and the sub-partitioning structure 51 and a source-side select gate line provided between the other of the adjacent partitioning structures 40 and the sub-partitioning structure 51. In this way, as described below, it is possible to reduce parasitic capacitance between the conductive layer 21 that functions as a word line and a channel of a cell transistor, and to reduce power consumption.

If the sub-partitioning structure 51 were not provided, all source-side select gate lines provided between adjacent partitioning structures 40 would be controlled into an ON state or an OFF state during read operation. Consequently, the potential of the source region 80 would substantially be applied through the source-side select gate line placed in an ON state to a channel of a NAND string set to an unselected state by the drain-side select gate line placed in an OFF state. Accordingly, in the NAND string placed in an unselected state, a potential difference would occur between the word line and the channel. That is, in the NAND string placed in an unselected state, parasitic capacitance would be present between the word line and the channel. As a result, charging time would be required for charging the parasitic capacitance, resulting in an increase in power consumption.

In the embodiment, since the sub-partitioning structure 51 is provided, it is possible to set the source-side select gate line of a NAND string placed in a selected state to an ON state and set the source-side select gate line of a NAND string placed in an unselected state to an OFF state. This makes it possible to set a channel of the NAND string placed in an unselected state into a floating state, so that in the NAND string placed in an unselected state, parasitic capacitance between the word line and the channel can substantially be eliminated. In this way, in the embodiment, it is possible to solve the problems described above.

Furthermore, in the embodiment, the sub-partitioning structure 51 is made of a constituent material that is the same as the constituent material of the pillar structure 30. That is, as described below, the sub-partitioning structure 51 can be formed in the process for forming the pillar structure 30. In this way, it is possible to prevent the increase of manufacturing processes for forming the sub-partitioning structure 51.

Furthermore, in the embodiment, as described below, a hole for forming the pillar structure portion 30P1 is formed separately from a hole for forming the pillar structure portion 30P2, and therefore, it is possible to reduce a variation in depth and shape of the hole. In this way, the variation of the pillar structure 30 can be reduced, and it is possible to reduce a variation in characteristics of the memory cell.

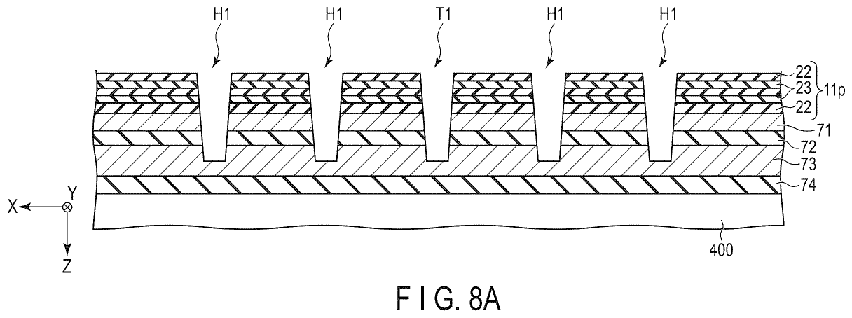

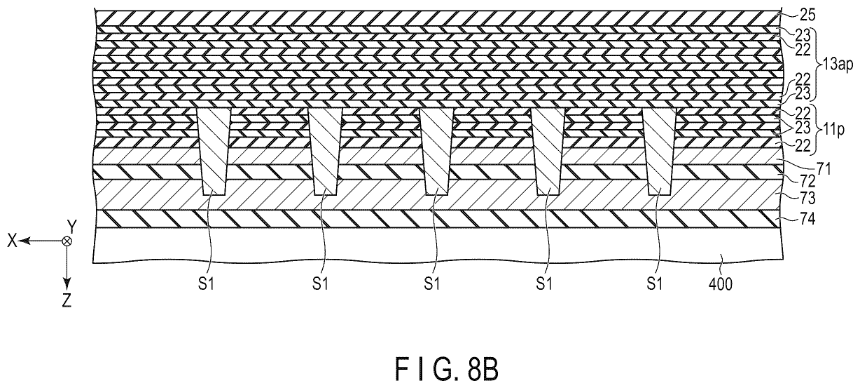

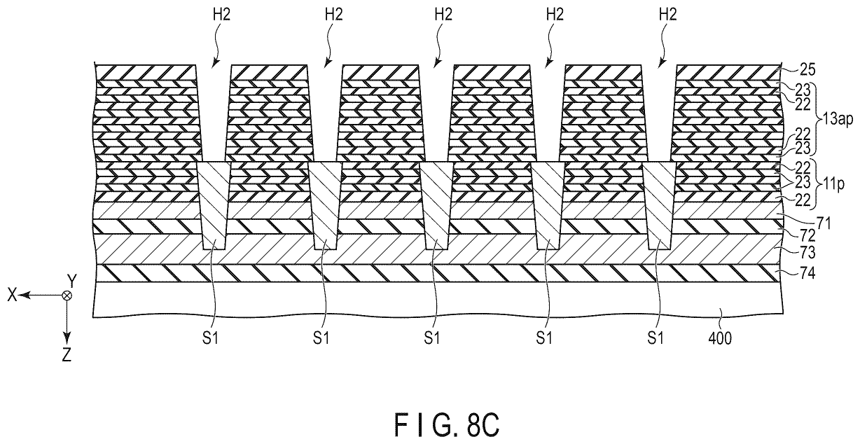

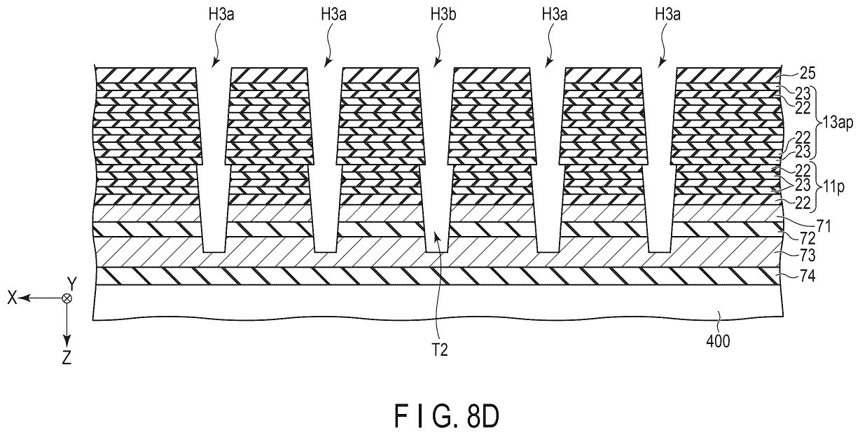

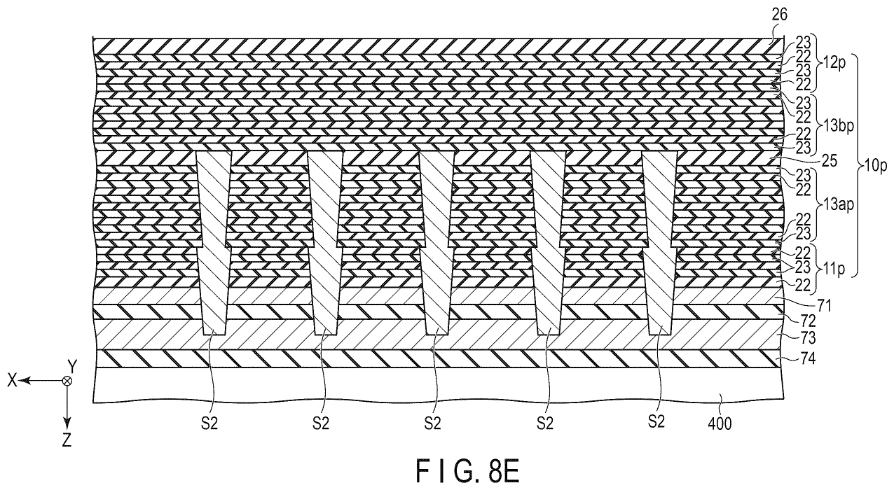

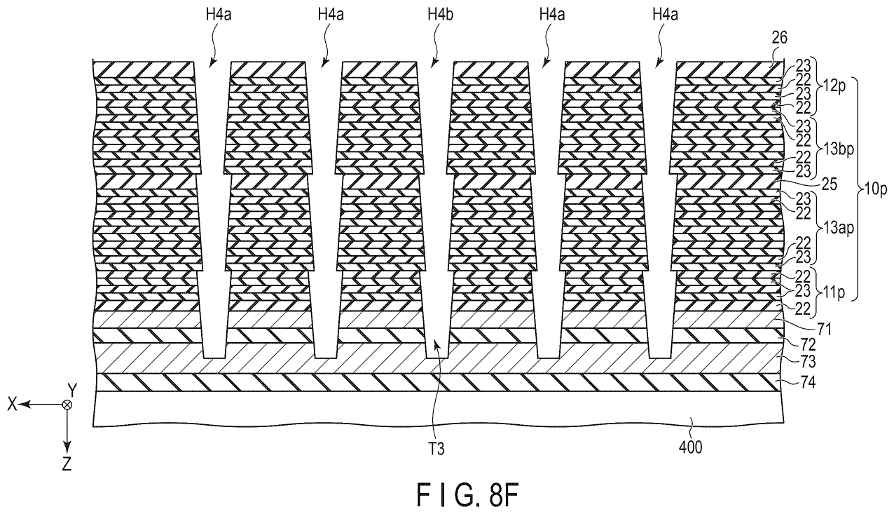

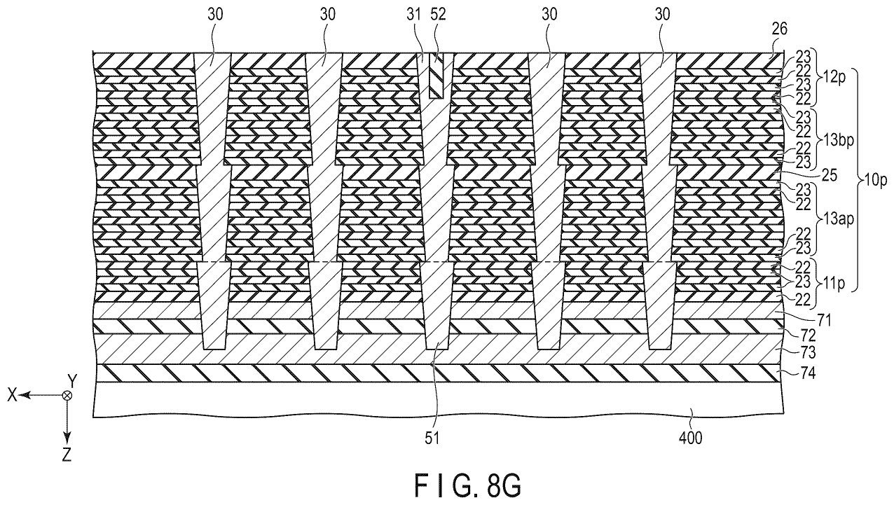

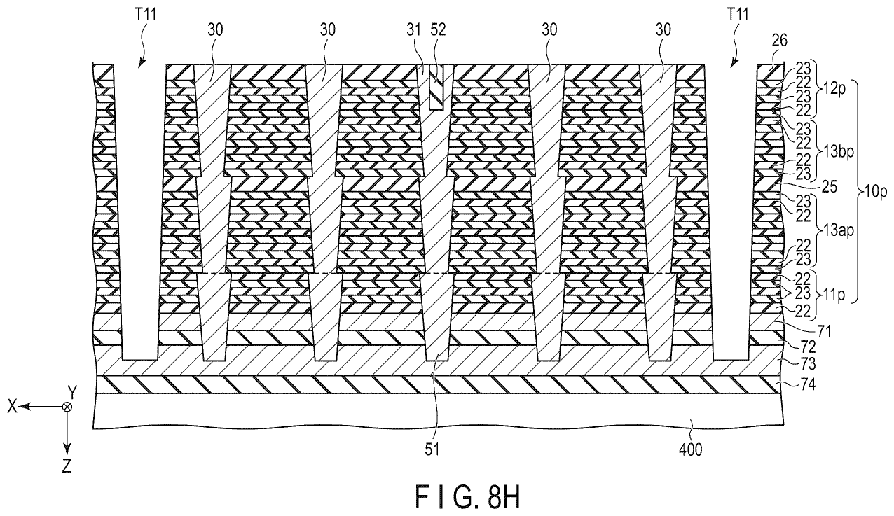

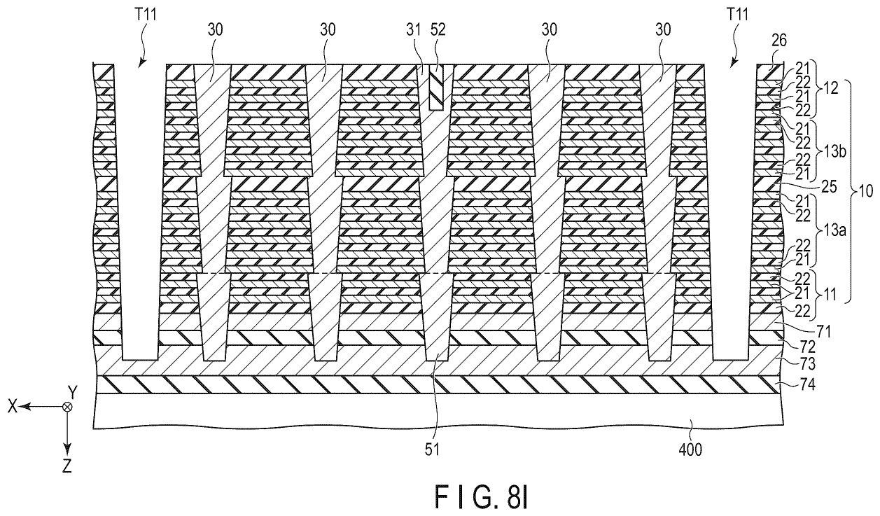

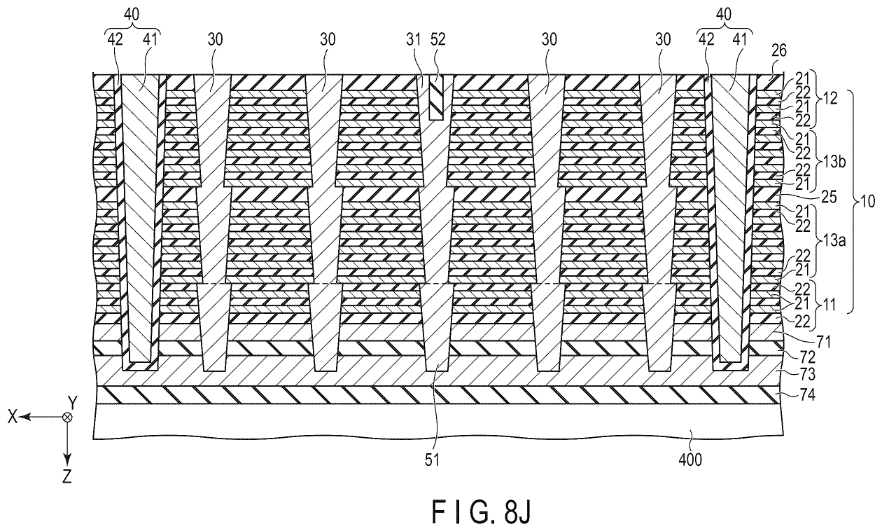

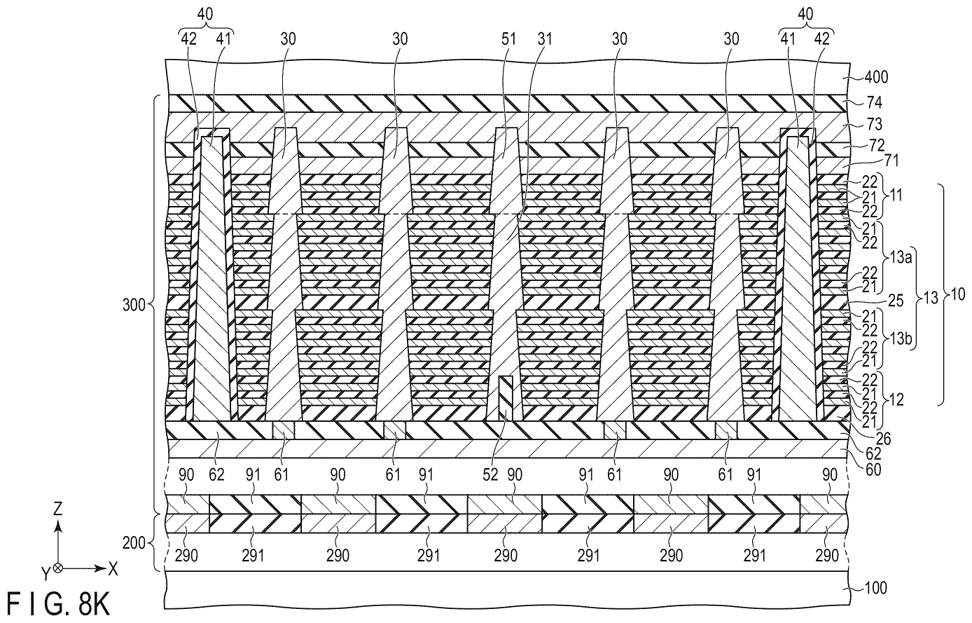

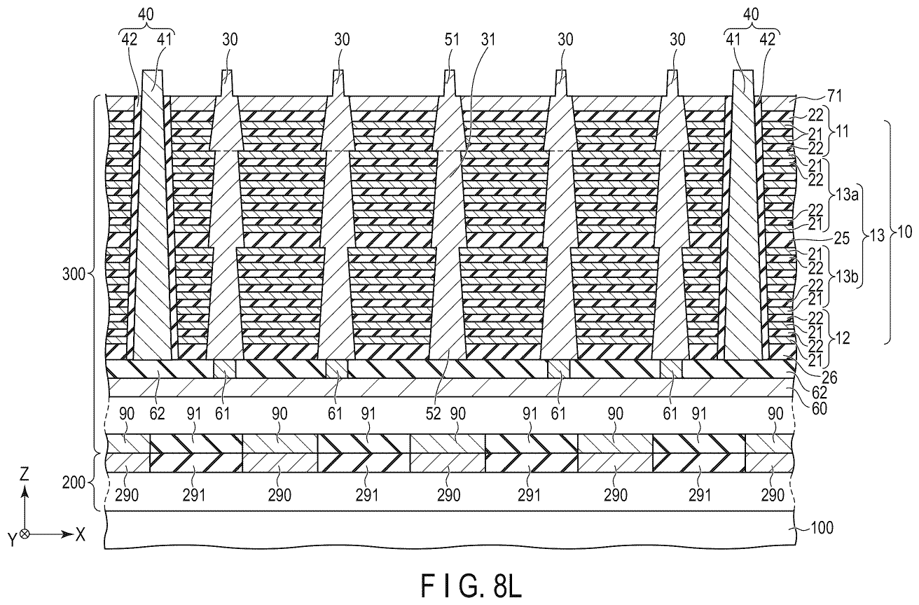

Next, a manufacturing method of a semiconductor storage device according to the embodiment will be described with reference to cross-sectional views illustrated in FIGS. 8A to 8L.

First, as illustrated in FIG. 8A, an insulating layer (for example, silicon oxide layer) 74, a semiconductor layer (for example, silicon layer) 73, an insulating layer (for example, silicon oxide layer) 72, and a semiconductor layer (for example, silicon layer) 71 are formed on a semiconductor substrate 400 for forming the memory region 300 in this order. Subsequently, a preparatory stacked-body portion 11p for the stacked-body portion 11 is formed. The preparatory stacked-body portion 11p has a structure in which a sacrificial layer (for example, silicon nitride layer) 23 and an insulating layer (for example, silicon oxide layer) 22 are alternately stacked. A hole H1 for the pillar structure portion 30P1 and a trench T1 for the sub-partitioning structure 51 are formed in the thus obtained structure in the common processes.

Next, as illustrated in FIG. 8B, sacrificial layers S1 are formed in the hole H1 and the trench T1. Subsequently, a preparatory stacked-body portion 13ap for the sub-stacked portion 13a of the stacked-body portion 13 is formed on the thus obtained structure. The preparatory stacked-body portion 13ap is also formed by using a material that is the same as that of the preparatory stacked-body portion 11p. Furthermore, an insulating layer (for example, silicon oxide layer) 25 is formed on the preparatory stacked-body portion 13ap.

Next, as illustrated in FIG. 8C, a hole H2 that reaches a sacrificial layer S1 is formed in the structure obtained in the process in FIG. 8B.

Next, as illustrated in FIG. 8D, the sacrificial layer S1 is removed. In this way, a hole H3a is formed in a region in which the pillar structure 30 is formed, and a trench T2 and a hole H3b are formed in a region in which the sub-partitioning structure 51 and the dummy pillar structure 31 are formed.

Next, as illustrated in FIG. 8E, sacrificial layers S2 are formed in the hole H3a, the hole H3b, and the trench T2. Subsequently, a preparatory stacked-body portion 13bp for the sub-stacked portion 13b of the stacked-body portion 13 and a preparatory stacked-body portion 12p for the stacked-body portion 12 are formed on the thus obtained structure. The preparatory stacked-body portions 13bp and 12p are also formed by using a material that is the same as that of the preparatory stacked-body portion 11p. Furthermore, an insulating layer (for example, silicon oxide layer) 26 is formed on the preparatory stacked-body portion 12p. In this way, a preparatory stacked body 10p is obtained.

Next, as illustrated in FIG. 8F, holes that reach the sacrificial layer S2 are formed in the preparatory stacked-body portions 13bp and 12p and the insulating layer 26, which have been formed in the processes in FIG. 8E. Furthermore, the sacrificial layer S2 is removed through the thus obtained hole. In this way, a hole H4a is formed in a region in which the pillar structure 30 is formed, and a trench T3 and a hole H4b are formed in a region in which the sub-partitioning structure 51 and the dummy pillar structure 31 are formed.

Next, as illustrated in FIG. 8G, a stacked film in which a plurality of layers are stacked is formed in the hole H4a, the hole H4b, and the trench T3 in the common processes. In this way, the pillar structure 30, the dummy pillar structure 31, and the sub-partitioning structure 51 are obtained. Furthermore, the sub-partitioning structure 52 is obtained by forming a trench for the sub-partitioning structure 52 and filling the trench with a predetermined material.

Next, as illustrated in FIG. 8H, a trench T11 for the partitioning structure 40 that penetrates the preparatory stacked body 10p is formed.

Next, as illustrated in FIG. 8I, a replacing process is carried out. Specifically, the sacrificial layers 23 are removed through the trench T11 to form a plurality of spaces, and the conductive layers 21 are formed in the spaces. In this way, the stacked body 10 is obtained.

Next, as illustrated in FIG. 8J, the partitioning structure 40 that includes the conductive layer 41 and the insulating layer 42 is formed in the trench T11.

Next, a structure illustrated in FIG. 8K is formed. Specifically, an insulating layer 62, the contact electrode 61, and the bit line 60 are formed on the structure obtained in the processes in FIG. 8J. Furthermore, a plurality of bonding electrodes 90 isolated by the insulating layers 91 are formed. In this way, the memory region 300 is formed. Thereafter, a substrate formed from the semiconductor substrate 400 on which the memory region 300 is formed and a substrate formed from the semiconductor substrate 100 on which the control-circuit region 200 is formed are bonded together. Specifically, the bonding electrode 90 provided in the memory region 300 and the bonding electrode 290 provided in the control-circuit region 200 are bonded together.

Next, as illustrated in FIG. 8L, the semiconductor substrate 400, the insulating layer 74, the semiconductor layer 73, and the insulating layer 72 are removed. Furthermore, the insulating layers (30b, 30c, and 30d) exposed in the first end portion of the pillar structure 30, the insulating layers (51b1, 51c1, 51d1, 51b2, 51c2, and 51d2) exposed in the first end portion of the sub-partitioning structure 51, and the insulating layer 42 exposed in the first end portion of the partitioning structure 40 are removed. In this way, each first end portion of the semiconductor layer 30a of the pillar structure 30, the semiconductor layers 51a1 and 51a2 of the sub-partitioning structure 51, and the conductive layer 41 of the partitioning structure 40 is exposed.

Thereafter, the source region 80 that includes the semiconductor layer 80a (for example, doped silicon layer) and the metal layer 80b (for example, tungsten layer) is formed on the structure obtained in the processes in FIG. 8L, and the insulating region 81 is formed on the source region 80 to obtain the structure as illustrated in FIG. 4. Note that impurities such as phosphorus doped into the semiconductor layer 80a may be diffused in the semiconductor layer 71 through a heat treatment performed when the semiconductor layer 80a is formed.

As described above, it is possible by using the above-described manufacturing method to effectively produce the advantageous effects of the embodiment as already described.

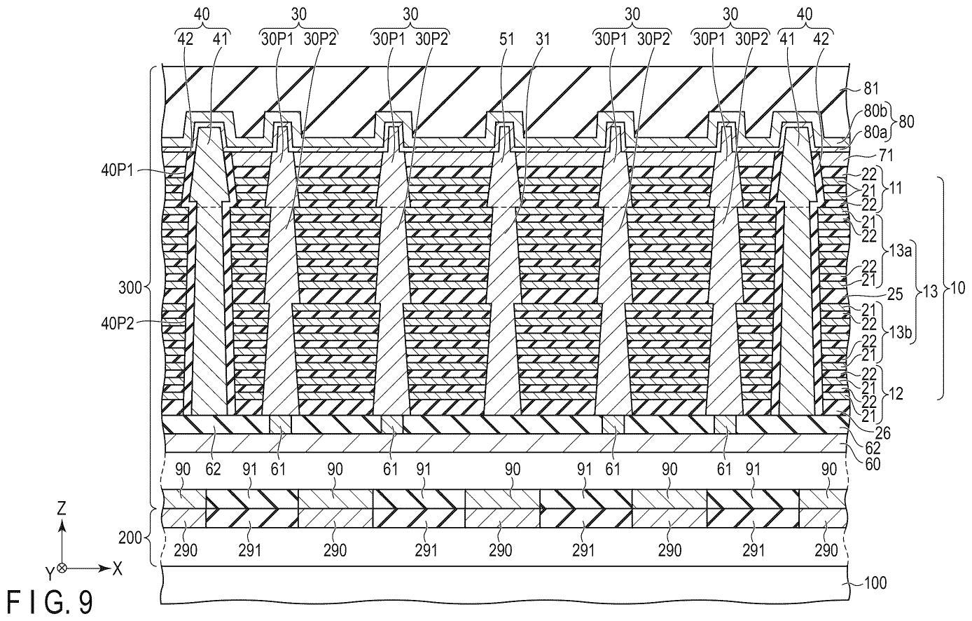

FIG. 9 schematically illustrates a cross-sectional view of a semiconductor storage device according to a modification of the embodiment.

In the modification, the partitioning structure 40 includes a partitioning structure portion 40P1 that includes a portion provided in the stacked-body portion 11 and a partitioning structure portion 40P2 that includes a portion provided in the stacked-body portions 12 and 13. A step is provided at a boundary between the partitioning structure portion 40P1 and the partitioning structure portion 40P2. That is, the side surface of the partitioning structure 40 has a step at a position corresponding to a position in a plane including a boundary between the stacked-body portion 11 and the stacked-body portion 13.

In the modification, when the hole H1 for the pillar structure portion 30P1 and the trench T1 for the sub-partitioning structure 51 are formed in the common processes in the processes in FIG. 8A, a trench for the partitioning structure portion 40P1 is also formed in the common processes. Furthermore, when the sacrificial layer S1 is formed in the processes in FIG. 8B, the sacrificial layer S1 is also formed in the trench for the partitioning structure portion 40P1. Thereafter, in the processes in FIG. 8I, a trench for the partitioning structure portion 40P2 that reaches the sacrificial layer S1 for the partitioning structure portion 40P1 is formed, and further a trench for the partitioning structure 40 is formed by removing the sacrificial layer S1 for the partitioning structure portion 40P1. Any other basic processes are the same as the processes of the above-described embodiment.

In the modification, the basic structure and the basic manufacturing method are also the same as those of the above-described embodiment, and it is also possible to produce the advantageous effects same as those of the above-described embodiment in the modification.

In the above-described embodiment and the modification, the memory region 300 formed on the semiconductor substrate 400 and the control-circuit region 200 formed on the semiconductor substrate 100 are bonded together to form the semiconductor storage device, whereas it may be possible to form the control-circuit region 200 on the semiconductor substrate on which the memory region 300 is formed. In this case, it is also possible to produce the advantageous effects same as those of the above-described embodiment by forming the memory region 300 same as that of the above-described embodiment or modification. However, in this case, the stacked body 10, the pillar structure 30, the dummy pillar structure 31, the partitioning structure 40, the sub-partitioning structure 51, the sub-partitioning structure 52, and the like are formed after the source region 80 is formed.

While certain embodiments have been described, these embodiments have been presented by way of example only, and are not intended to limit the scope of the inventions. Indeed, the novel devices and methods described herein may be embodied in a variety of other forms; furthermore, various omissions, substitutions, and changes in the form of the embodiments described herein may be made without departing from the spirit of the inventions. The accompanying claims and their equivalents are intended to cover such forms or modification as would fall within the scope and spirit of the inventions.

What is claimed is

1. A semiconductor storage device, comprising:
a stacked body in which a plurality of conductive layers are stacked and spaced apart from one another in a first direction, the stacked body including a first stacked-body portion including one or more first conductive layers included in the plurality of conductive layers and each functioning as a first select gate line for a NAND string, a second stacked-body portion including one or more second conductive layers included in the plurality of conductive layers and each functioning as a second select gate line for the NAND string, and a third stacked-body portion including a plurality of third conductive layers provided between the first stacked-body portion and the second stacked-body portion and included in the plurality of conductive layers, the plurality of third conductive layers each functioning as a word line for the NAND string;
a plurality of main partitioning structures each extending in the first direction and a second direction intersecting the first direction in the stacked body to partition the plurality of conductive layers in a third direction intersecting the first and second directions, the plurality of main partitioning structures including a first main partitioning structure and a second main partitioning structure that are adjacent to each other in the third direction;
a plurality of main pillar structures provided between the first and second main partitioning structures in the third direction, each of the plurality of main pillar structures extending in the first direction in the stacked body and functioning as the NAND string, each of the plurality of main pillar structures including a first laminate of layers formed inward from an outer peripheral surface of the main pillar structure, the first laminate of layers including a first semiconductor layer and extending in the first direction along the outer peripheral surface;
a first sub-partitioning structure provided between the first and second main partitioning structures in the third direction, provided to include a first side surface and a second side surface that are opposite to each other in the third direction, and extending in the first stacked-body portion in the first and second directions without extending in the second and third stacked-body portions to partition the one or more first conductive layers in the third direction between the first and second main partitioning structures, the first sub-partitioning structure including:
a first stacked-film portion of a second laminate of layers formed inward from the first side surface, the second laminate of layers including a second semiconductor layer and extending in the first and second directions along the first side surface; and
a second stacked-film portion of a third laminate of layers formed inward from the second side surface, the third laminate of layers including a third semiconductor layer and extending in the first and second directions along the second side surface, the second stacked-film portion being opposite to the first stacked-film portion in the third direction; and
a source region provided on a side of a first end surface of the stacked body in the first direction, the source region being electrically connected to a first end portion in the first direction of the first semiconductor layer included in each of the plurality of main pillar structures, wherein
materials of the second laminate of layers formed inward from the first side surface in the first stacked-film portion are same as materials of the first laminate of layers formed inward from the outer peripheral surface in each of the plurality of main pillar structures, respectively, and
materials of the third laminate of layers formed inward from the second side surface in the second stacked-film portion are same as the materials of the first laminate of layers formed inward from the outer peripheral surface in each of the plurality of main pillar structures, respectively.

2. The semiconductor storage device of claim 1, wherein each layer of the first laminate in each of the plurality of main pillar structures has a tubular shape, and
each layer of the second laminate in the first stacked-film portion and each layer of the third laminate in the second stacked-film portion have a plate-like shape.

3. The semiconductor storage device of claim 2, wherein
each of the plurality of main pillar structures further includes a first layer that extends in the first direction and has a columnar shape inside the first laminate of layers in each of the plurality of main pillar structures, and
the first sub-partitioning structure further includes a second layer that extends in the first and second directions, has a plate-like shape, and is made of a material same as a material of the first layer between the second laminate and third laminate.

4. The semiconductor storage device of claim 1, wherein
a side surface of each of the plurality of main pillar structures has a step at a position corresponding to a position in a plane including a boundary between the first stacked-body portion and the third stacked-body portion.

5. The semiconductor storage device of claim 1, further comprising:
a plurality of dummy pillar structures each extending in the first direction at least up to the first sub-partitioning structure in the third stacked-body portion, the plurality of dummy pillar structures being unfunctional as a NAND string, each of the plurality of dummy pillar structures including a fourth laminate of layers formed inward from an outer peripheral surface of the dummy pillar structure, the fourth laminate of layers including a fourth semiconductor layer and extending in the first direction along the outer peripheral surface thereof, wherein
materials of the fourth laminate of layers formed inward from the outer peripheral surface thereof in each of the plurality of dummy pillar structures are same as the materials of the first laminate of layers formed inward from the outer peripheral surface of the main pillar structure in each of the plurality of main pillar structures, respectively.

6. The semiconductor storage device of claim 5, wherein
each of the plurality of main pillar structures includes a first pillar structure portion that includes a portion provided in the first stacked-body portion, and a second pillar structure portion that includes a portion provided in the second and third stacked-body portions, and
with a surface that includes the first end face of the stacked body being as a reference surface, a distance from the reference surface to a boundary between the first pillar structure portion and the second pillar structure portion corresponds to a distance from the reference surface to a boundary between the first sub-partitioning structure and the plurality of dummy pillar structures.

7. The semiconductor storage device of claim 5, wherein at a same distance from a reference surface that includes the first end surface of the stacked body, a size of a cross-sectional plane perpendicular to the first direction of each of the plurality of dummy pillar structures is substantially same as a size of a cross-sectional plane perpendicular to the first direction of each of the plurality of main pillar structures.

8. The semiconductor storage device of claim 5, wherein as viewed in the first direction, a position of a center in the third direction of a pattern of each of the plurality of dummy pillar structures substantially coincides with a position of a center in the third direction of a pattern of the first sub-partitioning structure.

9. The semiconductor storage device of claim 1, wherein a distance in the third direction between the first main partitioning structure and the first sub-partitioning structure is substantially same as a distance in the third direction between the second main partitioning structure and the first sub-partitioning structure.

10. The semiconductor storage device of claim 1, wherein
the plurality of main pillar structures are arranged in the second direction, and
a first number of rows of the main pillar structures arranged in the second direction between the first main partitioning structure and the first sub-partitioning structure among the plurality of main pillar structures is same as a second number of rows of the main pillar structures arranged in the second direction between the second main partitioning structure and the first sub-partitioning structure among the plurality of main pillar structures.

11. The semiconductor storage device of claim 1, further comprising:
a second sub-partitioning structure provided between the first and second main partitioning structures and extending in the second stacked-body portion in the first and second directions without extending in the first and third stacked-body portions to partition the one or more second conductive layers in the third direction between the first and second main partitioning structures.

12. The semiconductor storage device of claim 11, wherein as viewed in the first direction, a position of the second sub-partitioning structure in the third direction coincide with a position of the first sub-partitioning structure in the third direction.

13. The semiconductor storage device of claim 1, wherein
no partitioning structure is provided, which extends in the first stacked-body portion in the first and second directions without extending in the second and third stacked-body portions to partition off the one or more first conductive layers in the third direction between the first and second main partitioning structures, between the first and second main partitioning structures except the first sub-partitioning structure.

14. The semiconductor storage device of claim 1, further comprising:
a bit line provided on a side of a second end surface of the stacked body in the first direction and electrically connected to a second end portion in the first direction of the first semiconductor layer included in each of two or more predetermined main pillar structures among the plurality of main pillar structures.

15. The semiconductor storage device of claim 14, wherein the bit line extends in the third direction.

16. The semiconductor storage device of claim 1, wherein a first end portion of the first sub-partitioning structure in the first direction reaches the source region.

17. The semiconductor storage device of claim 1, wherein a first end portion of each of the first and second main partitioning structures in the first direction reaches the source region.

18. The semiconductor storage device of claim 1, wherein a side surface of each of the first and second main partitioning structures has a step at a position corresponding to a position in a plane including a boundary between the first stacked-body portion and the third stacked-body portion.

19. The semiconductor storage device of claim 1, further comprising:
a semiconductor substrate; and
a control circuit region between the semiconductor substrate and a memory region that includes the stacked body, the control circuit region including a control circuit configured to control operation of the NAND string.

20. The semiconductor storage device of claim 19, wherein
the memory region further includes a plurality of first bonding electrodes,
the control circuit region further includes a plurality of second bonding electrodes, and
the memory region and the control circuit region are bonded to each other with the plurality of first bonding electrodes being electrically connected to the plurality of second bonding electrodes.
